(19) United States
(12) Patent Application Publication
(10) Pub. No.: US 2021/0203362 A1
(43) Pub. Date: Jul. 1, 2021

(54) METHOD OF INTERLEAVED POLAR CODES AND INTERLEAVED POLAR ENCODER USED THEREIN

(71) Applicant: NATIONAL CHUNG CHENG UNIVERSITY, Chiayi (TW)

(72) Inventor: Mao-Ching Chiu, Chiayi (TW)

(21) Appl. No.: 16/899,787

(22) Filed: Jun. 12, 2020

(30) Foreign Application Priority Data
Dec. 31, 2019 (TW) 108148715

(51) Int. Cl. H03M 13/15; H03M 13/27

(52) U.S. Cl. CPC H03M 13/15; H03M 13/2735

(57) ABSTRACT

A method for generating an interleaved polar code is provided and including: performing a channel selection algorithm on message bits to generate an interleaved polar sequence; and performing interleaved encoding on the message bits to generate an interleaved polar code according to the interleaved polar sequence. The process performed at each encoding stage includes an interleaving process and a polar process.

### CROSS-REFERENCE TO RELATED APPLICATION

This application claims the priority of Taiwanese patent application No. 108148715, filed on Dec. 31, 2019, which is incorporated herewith by reference.

### BACKGROUND OF THE INVENTION

### 1. Field of the Invention

The present invention relates to a method for communication coding and channel selection, in particular to a generation method of interleaved polar codes and system used therein.

### 2. The Prior Arts

Polar codes are the first family of linear codes that achieve the capacity of symmetric binary-input discrete noiseless channels under a low-complexity successive cancellation (SC) decoding algorithm as the block length approaches infinity. A polar code of length N=2^{M} transfers N identical and independent channels into N synthesized channels with different qualities. The qualities of synthesized channels approach two extremes, either a noiseless channel or a pure-noise channel, as the block length N approaches infinity. The fraction of the noiseless channels approaches the channel capacity as N approaches infinity. Therefore, the noiseless channels are used for transmitting message bits and the bits transmitted on other channels are set to fixed values known by both encoder and decoder. For finite block lengths, the K best synthesized channels, termed unfrozen bit channels specified by an index set, are selected for transmitting message bits.

However, polar codes are weak at short to moderate block lengths under the SC decoding algorithm. In order to improve the performance of polar codes, a successive cancellation list decoding algorithm was proposed. The SCL decoder approaches the performance of the maximum-likelihood (ML) decoder as the list size L becomes large. However, polar codes are still weak even under ML decoding. It is well known that the minimum Hamming weight of codewords, denoted as dₘᵢₙ, and its multiplicity, denoted as B_{dmin}, dominate the performance of a linear code at high SNRs. The problem of polar codes is that they often result in a small dₘᵢₙ with large B_{dmin} under conventional bit channel selection algorithms. The reason is that the conventional bit channel selection algorithms are optimized for SC decoding. They do not take into account the performance under ML decoding. To strengthen polar codes, a serial concatenation of a cyclic redundancy check (CRC) code and a polar code, termed the CRC-aided polar code, was found to be effective to improve the performance under the SCL decoding algorithm. The performance levels of CRC-aided polar codes under the SCL decoding algorithm are better than those of LDPC and turbo codes. As the SCL decoder is capable to achieve the ML performance, it is important to study the block error rate (BLER) of polar codes under the ML decoder. The BLERs of polar codes rely on simulations that are time-consuming. A possible way to analyze the BLER performance of a coding scheme is to use the BLER upper bound which is a function of the weight enumerating function (WEF) as that used to analyze turbo codes. However, if the code size is large, obtaining the exact WEF of a polar code with the heuristic method is prohibitively complex.

The fifth generation mobile communication system generally uses a polar code as an error correction code for the control channel. However, in the case of short and medium codes, there is a problem of poor performance of the polar code. Therefore, in the 5G standard, the polar code additionally requires a cyclic redundancy check (CRC) code.

Although other existing technologies have also proposed to determine encoding method of the polar code, an interleaver designed for interleaving the polar code, or interleaving punctured polar code based on the channel condition, information block length, encoding length, and signal-to-noise ratio, but it still cannot further solve the performance problem of polar codes at short to moderate block lengths.

Therefore, it is necessary to propose a method that can solve the problem of insufficient performance of polar codes in short and medium length, and make it better than the performance of low density check codes (LDPC) or turbo codes.

### SUMMARY OF THE INVENTION

An object of the present invention is to propose an encoding method and a corresponding channel selection algorithm that can solve the problem of insufficient performance of polar codes in short and medium lengths, and make it better than the performance of low density check code (LDPC) or turbo code.

According to an embodiment of the present invention, a method is provided for generating an interleaved polar code and including an interleaving process and a polarizing process during process of each encoding layer, and the interleaving process and the polarizing process is expressed by the following equation:

C_{m,j}=C_{m-1,2j}Π_{m-1,j}+C_{m-1,2j+1}|C_{m-1,2j+1}.

According to another embodiment of the present invention, an interleaved polar encoder configured for generating an interleaved polar code is provided, which includes a plurality of interleavers performing an interleaving process and a polarizing process during process of each encoding layer.

The idea of the new construction is to insert interleavers in the intermediate stages of the polar code encoder. The ensemble of interleaved polar codes is formed by considering all possible permutations of interleavers. The regular polar code is just one realization of the ensemble of interleaved polar codes. It should be noted that interleaved polar codes have the same polarization effect as polar codes. The reason is that both interleaved polar code and polar code of the same block length produce the same synthesized channels. Therefore, conventional bit channel selection algorithms designed for polar codes can be employed for interleaved polar codes. However, under conventional bit channel selection algorithms, it's been found that interleaved polar codes are still weak, though they perform slightly better than polar codes.

One advantage of interleaved polar codes is that the weight enumerating function (WEF) averaged over the ensemble of interleaved polar codes can be evaluated in a recursive form. With the WEF available, the upper bound on the block error rate (BLER) under ML decoding, termed simple bound, can be calculated. Therefore, the bit channel selection algorithm that aims to optimize the BLER upper bound under ML decoding can be employed. However, if only BLER upper bound under ML decoding is considered in the bit channel selection algorithm, the BLER performance may be seriously degraded under SCL decoding with a limited list size. The reason is that the polarization effect is a key feature for the SCL decoder to be effective. The SCL decoder with a limited list size may not be able to approach the ML performance without the polarization effect. Therefore, both the polarization effect and the BLER upper bound under ML decoding should be considered in the design of the bit channel selection algorithm.

In the generation method of interleaved polar sequence of the present invention, a channel selection algorithm is performed on message bits first to generate an interleaved polar sequence, then interleaved polarization is performed on the message bits to generate the interleaved polar code. In this way, the problem of insufficient performance of polar codes in short and medium codes can be solved, and the performance thereof is better than that of low density check code (LDPC) or turbo code.

Those with ordinary knowledge in the technical field will understand that the effects that can be achieved through the disclosure of the present invention are not limited to those specifically described above, and the advantages of the present invention will be more clearly understood from the above detailed description in conjunction with the drawings.

### BRIEF DESCRIPTION OF THE DRAWINGS

The present invention will be apparent to those skilled in the art by reading the following detailed description of a preferred embodiment thereof, with reference to the attached drawings, in which:

FIG. 1 illustrates a flowchart of a generation method of an interleaved polar code according to an embodiment of the present invention.

FIG. 2 illustrates a block diagram of a system using an interleaved polar code according to an embodiment of the present invention.

FIG. 3 illustrates a schematic diagram of a trellis connection of a conventional polar code.

FIG. 4 illustrates a schematic diagram of a trellis connection of an interleaved polar code according to an embodiment of the present invention.

FIG. 5 illustrates a flowchart of a partial method for generating an interleaved polar sequence according to an embodiment of the present invention.

### DETAILED DESCRIPTION OF THE PREFERRED EMBODIMENT

Polar codes are constructed from the generator matrix G₂^{⊗M} with

$${G}_{2} = [ \begin{matrix}1 & 0 \\ 1 & 1\end{matrix} ] ,$$

where ⊗M denotes the Mth Kronecker power. The synthesized channels seen by individual bits approach two extremes, either a noiseless channel or a pure-noise channel, as the block length N=2^{M} grows large. The fraction of noiseless channels is close to the channel capacity. Therefore, the noiseless channels, termed unfrozen bit channels, are selected for transmitting message bits while the other channels, termed frozen bit channels, are set to fixed values known by both encoder and decoder. Therefore, polar codes are the first family of codes that achieve the capacity of symmetric binary-input discrete memoryless channels under a low-complexity successive cancellation (SC) decoding algorithm as the block length N approaches infinity.

However, the performance of polar codes at short to moderate block lengths is disappointing under the SC decoding algorithm. Later, a successive cancellation list (SCL) decoding algorithm for polar codes was provided, which approaches the performance of the maximum-likelihood (ML) decoder as the list size L is large. However, the performance levels of polar codes are still inferior to those of low-density parity-check (LDPC) codes even under the ML decoder. To strengthen polar codes, a serial concatenation of a cyclic redundancy check (CRC) code and a polar code, termed the CRC-aided polar code, was found to be effective to improve the performance under the SCL decoding algorithm. The performance levels of CRC-aided polar codes under the SCL decoding algorithm are better than those of LDPC and turbo codes.

The interleaved polar code proposed here is randomized using interleavers between the inter-mediate stages of the polar code encoder. Codes constructed on the basis of this idea are called interleaved polar (interleaved polar) codes. The ensemble of interleaved polar codes is formed by considering all possible interleavers. The regular polar code is just one realization of the ensemble of interleaved polar codes. Based on the concept of uniform interleaver, i.e., all interleavers are selected uniformly at random from all possible permutations, the average WEF of a code selected at random from the ensemble of interleaved polar codes can be evaluated. The concept of uniform interleaver has also been used in the analysis of turbo codes. It should be noted that the WEF analysis here is not an approximation to the WEF of a polar code, but is an exact WEF averaged over the ensemble of interleaved polar codes. Based on the average WEF, a BLER upper bound can be used to evaluate the BLER performance averaged over the ensemble of codes. In this way, the BLER upper bounds can well predict the ML performance levels of interleaved polar codes at high SNRs. Besides, a specific realization of interleaved polar codes outperforms a regular polar code under the SCL decoder of the same list size.

However, interleaved polar codes and polar codes are still weak even under ML decoding. It is well known that the minimum Hamming weight of codewords, denoted as dₘᵢₙ and its multiplicity, denoted as B_{d}_{ₘᵢₙ}, dominate the performance of a linear code at high SNRs. The problem of polar codes is that they often result in a small dₘᵢₙ with large B_{d}_{ₘᵢₙ} under conventional bit channel selection algorithms. The reason is that the conventional bit channel selection algorithms are optimized for SC decoding. They do not take into account the performance under ML decoding. Due to the weakness of polar codes, concatenated codes, such as CRC-aided polar codes, are often considered in the design of polar codes. It should be noted that under SCL decoding, CRC-aided polar codes outperform LDPC codes and turbo codes. The reason for such superior performance is that the number of low-weight codewords whose message vectors pass the CRC check is dramatically reduced. Due to their superior performance, CRC-aided polar codes have been adopted for the control channel in the fifth generation (5G) new radio.

The present invention provides a new bit channel selection algorithm for interleaved polar codes. The new algorithm considers both the polarization effect and the BLER upper bound under ML decoding as design criteria. Since the sequence is designed for interleaved polar codes, the sequence is termed as the interleaved polar sequence (IPS). It's been shown that, with the IPS from the algorithm, stand-alone interleaved polar codes outperform the state-of-the-art 5G LDPC code at short to moderate block lengths. Since a polar code is just one realization of the ensemble of interleaved polar codes, the IPS can also be applied to polar codes. It has been found that the performance levels of stand-alone polar codes with IPS are worse than those of interleaved polar codes but are comparable to those of the 5G LDPC code.

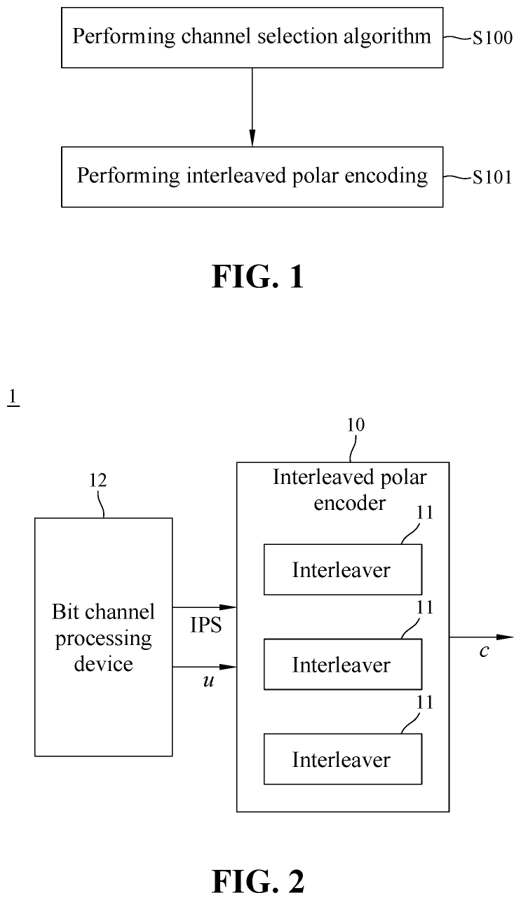

Referring to FIG. 1, FIG. 1 illustrates a flowchart of a generation method of an interleaved polar code according to an embodiment of the present invention. As shown in FIG. 1, step S100 performs a channel selection algorithm to generate an interleaved polar sequence IPS.

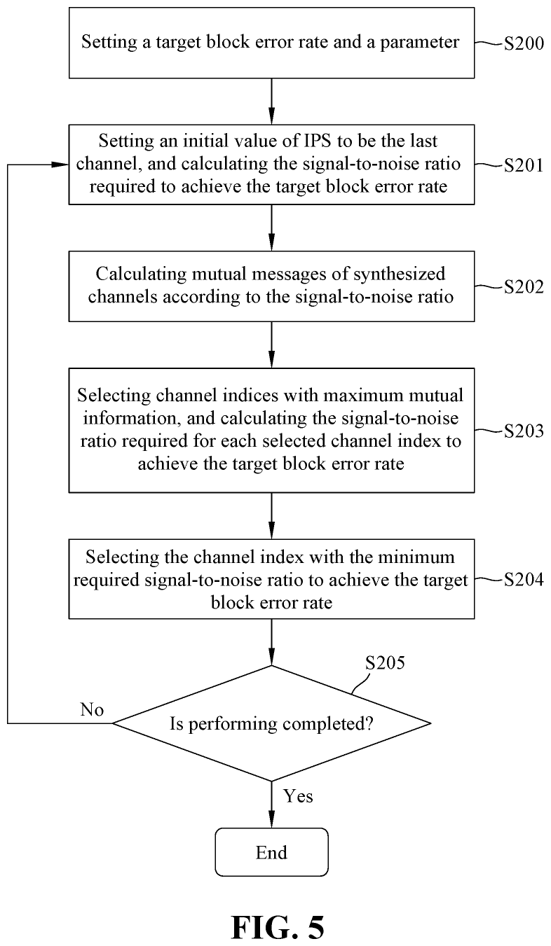

As to the detailed flow of step S100, referring to FIG. 5, as shown in FIG. 5, in the channel selection algorithm, step S200 is executed first, which sets a target block error rate BLER_{T}, and a parameter P.

Then step S201 is performed, in which an initial value of IPS is set to be the last channel N−1, and a signal-to-noise ratio (SNR) required to achieve the target block error rate BLER_{T} is calculated.

Then step S202 is performed, and mutual information of synthesized channels are calculated according to the SNR obtained in the previous step.

Then step S203 is performed, which selects P channel indices with maximum mutual information, and calculates the required SNR for each selected channel index to achieve the target block error rate BLER_{T}.

Step S204 is performed to select a channel index with the minimum required SNR to achieve the target block error rate BLER_{T}.

The above steps S202 to S204 are repeated N−1 times to obtain an interleaved polar sequence IPS.

In steps S201 and S203, a weight enumerating function (WEF) is used to calculate the signal-to-noise ratio required to achieve the target block error rate BLER_{T}.

Next, step S101 is performed, which performs interleaved polar encoding on the bit message vector u according to the interleaved polar sequence IPS, and includes interleaving process and polarizing process.

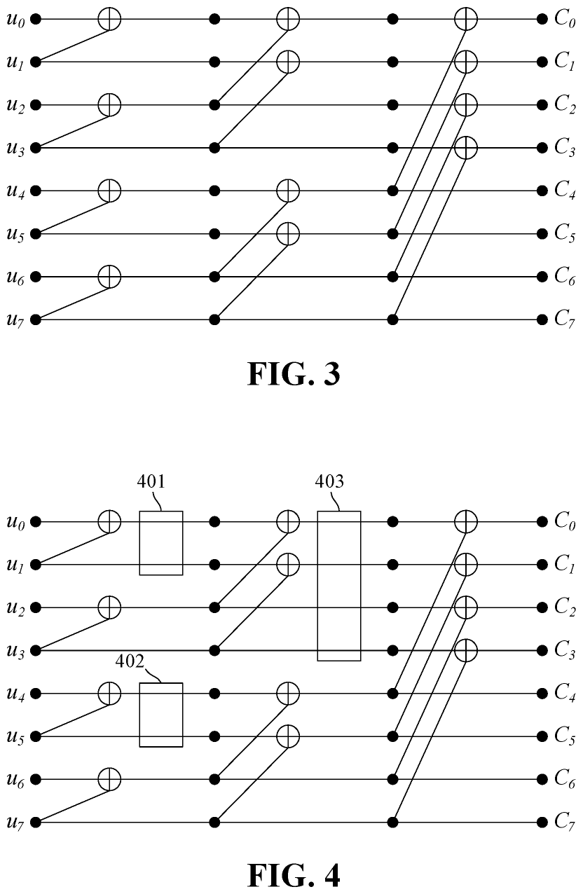

Referring to FIG. 3, FIG. 3 illustrates a schematic diagram of a trellis connection for a traditional polar code with N=8 and M=3. The number here is only for example, but not for limiting the present invention. M=3 represents a trellis connection with 3 layers, and ⊕ in FIG. 3 represents a binary addition.

It's been found that, in some embodiments, as M grows large, a synthesized channel approaches either a noiseless channel or a pure-noise channel. The fraction of noiseless channels is close to the channel capacity. Therefore, the noiseless channels are used for transmitting message bits while the other channels are set to transmit fixed values known by both encoder and decoder.

As shown in FIG. 4, the interleaved polar code of the present invention is generated with interleavers 401, 402, and 403 added to the trellis connection of traditional polar code to perform 3-layer encoding and interleaving process to generate an interleaved polar code C, the interleaved polar code C can be expressed by the following equation 2:

C_{m,j}=C_{m-1,2j}Π_{m-1,j}+C_{m-1,2j+1}|C_{m-1,2j+1} (2)

m=1, . . . , M, j=0, . . . 2^{M-m}−1, Π_{m-1,j} represents a matrix for the interleaving process, and the interleaved polar code C=C_{M,0} has the same polarization effect as the traditional polar code.

As shown in FIG. 4, as M=3 mentioned above, three interleaves Π_{1,0}, Π_{1,1}, and Π_{2,1}, represented by 401, 402, and 403 in FIG. 4, are used in the encoding stages (first stage and second stage) where the interleaving process is performed. That is, the interleaved encoding at each encoding stage includes interleaving process and polarizing process.

It should be noted that conventional bit channel selection algorithms consider only the polarization effect, i.e., only the synthesized channels with the best qualities are selected. Therefore, these algorithms are optimized under SC decoding, which often result in poor performance under SCL decoding or even ML decoding, the present invention differs from prior art in that both the polarization effect and the BLER upper bound under ML decoding are considered in the proposed algorithm.

Referring to FIG. 2, FIG. 2 illustrates a block diagram of the system 1 using an interleaved polar code according to an embodiment of the present invention. The system 1 includes an interleaved polar encoder 10 having three interleavers 11 and a bit channel processing device 12.

The number here corresponding to the above embodiment is only for example, and is not for limiting the present invention.

As in the above embodiment, the system 1 uses the bit channel processing device 12 to encode the message bit vector u. According to the interleaved polar sequence IPS, the interleaved polar encoder 10 performs interleaved polar encoding on the message bit vector u to form a codeword c. The three interleavers 11 interleave certain bits during the encoding process and generate the interleaved polar codeword c.

The three interleavers 11 respectively perform the interleaving process at each encoding level, that is, the above-mentioned interleaved encoding includes an interleaving process and a polarizing process at each encoding stage. The detailed method is described above and repeated here in the embodiment.

The present invention provides a new bit channel selection algorithm for interleaved polar codes which results in the interleaved polar sequence (IPS). Two parameters are used for the algorithm. One is the BLER target for optimization, the other one is the parameter used to control the trade-off between the polarization effect and the BLER upper bound under ML decoding. By proper selection of the parameter, it's been found that stand-alone interleaved polar codes with IPS outperform the state-of-the-art 5G LDPC code. Also, the performance levels of stand-alone polar codes with IPS are comparable to those of the 5G LDPC code. Therefore, interleaved polar codes and polar codes are not weak at short to moderate block lengths.

By using the method of the present invention, a channel selection algorithm is performed on the message bits to generate an interleaved polar sequence, and then the message bits are interleaved to generate the interleaved polar code according to the interleaved polar sequence, which has good performance under short, medium and long length, and has better performance than the low density check code (LDPC) or turbo code.

It is obvious for those having ordinary knowledge in the technical field that the present invention may be implemented in other specific forms without departing from the spirit of the present invention. Therefore, the above description should not be construed as limiting, but as illustrative in all aspects.

The scope of the invention should be determined by a reasonable interpretation of the scope of the appended claims, and all changes that come within the scope of equivalents of the invention are included in the scope of the invention.

What is claimed is:

1. A method for generating an interleaved polar code, which includes an interleaving process and a polarizing process during process of each encoding layer, and the interleaving process and the polarizing process is expressed by the following equation:
C_{m,j}=C_{m-1,2j}Π_{m-1,j}+C_{m-1,2j+1}|C_{m-1,2j+1}
wherein C_{M,0} indicates the interleaved polar code with a block length of 2^{M},
and m=1, . . . , M, j=0, . . . , 2^{M-m}−1, Π_{m-1,j} indicates a matrix for the interleaving process.

2. The method as claimed in claim 1, wherein a single optimized channel index is selected from a plurality of channel indices for each channel selection until all channels are selected.

3. The method as claimed in claim 2, wherein an algorithm of the channel selection includes:
a) setting a target block error rate and a parameter;
b) selecting the last channel index and calculating the required signal-to-noise ratio to achieve the target block error rate
c) calculating the mutual information of synthesized channels according to the signal-to-noise ratio calculated in previous step;
d) selecting a number of channel indices with the largest mutual information;
e) finding the optimized channel index among the selected channel indices from previous step, which has the smallest required signal-to-noise ratio to achieve the target block error rate; and
f) performing steps c)˜e) again with the optimized channel index repeatedly;
wherein the number equals the parameter.

4. The method as claimed in claim 3, wherein weight enumerating function (WEF) is used in step b) and step e) for calculating the signal-to-noise ratio required to achieve the target block error rate.

5. The method as claimed in claim 3, wherein step b) includes setting the initial IPS as the last channel, and calculating the signal-to-noise ratio required to achieve the target block error rate.

6. The method as claimed in claim 3, wherein step e) includes selecting channel indices of the maximum mutual information, and calculating the signal-to-noise ratio required for each selected channel index to achieve the target block error rate.

7. The method as claimed in claim 3, wherein the optimized channel index in step e) is the channel index with the smallest required signal-to-noise ratio.

8. The method as claimed in claim 3, wherein step c)-step e) are repeatedly performed N−1 times, N is the length of the block.

9. An interleaved polar encoder configured for generating an interleaved polar code, and comprising:
a plurality of interleavers performing an interleaving process during process of each encoding layer;
wherein encoding of interleaved polar code includes an interleaving process and a polarizing process during the process of each encoding layer.

10. The interleaved polar encoder as claimed in claim 9, wherein the interleaving process and the polarizing process is expressed by the following equation:
C_{m,j}=C_{m-1,2j}Π_{m-1,j}+C_{m-1,2j+1}|C_{m-1,2j+1}
wherein C_{M,0} indicates the interleaved polar code with a block length of 2^{M},
and m=1, . . . , M, j=0, . . . , 2^{M-3}−1, Π_{m-1,j} indicates a matrix for the interleaving process.
